(19) United States
(12) Patent Application Publication
(10) Pub. No.: US 2024/0080970 A1
(43) Pub. Date: Mar. 7, 2024

(54) ELECTRONIC CIRCUIT PACKAGES

(71) Applicant: Apple Inc., Cupertino, CA (US)

(72) Inventors: Leilei ZHANG, Sannyvale, CA (US); Abhay Maheshwari, Monte Serno, CA (US); Ali N. Ergun, Sunnyvale, CA (US); Arun Chawan, Berkeley, CA (US)

(73) Assignee: Apple Inc., Cupertino, CA (US)

(21) Appl. No.: 18/122,339

(22) Filed: Mar. 16, 2023

Related U.S. Application Data
(63) Continuation of application No. 63/404,280, filed on Sep. 7, 2022.

(51) Int. Cl. H05K 1/02; H01L 23/31; H01L 25/16; H05K 1/18; H05K 3/28

(52) U.S. Cl. CPC H05K 1/028; H01L 23/3135; H01L 25/162; H05K 1/189; H05K 3/284; H01L 25/0655

(57) ABSTRACT

Various embodiments of a flexible circuit package with a high-modulus molding compound layer are disclosed. A flexible circuit package includes a substrate with first and second regions. The first region is configured to bend. The flexible circuit package further includes a conductive line disposed on the second region, an electronic component disposed on the conductive line, and a molding compound layer disposed on the second region and surrounding the electronic component. A modulus of the molding compound layer is greater than a modulus of the substrate and the molding compound layer is configured to prevent the second region from bending.

### CROSS-REFERENCE TO RELATED APPLICATION

This application claims the benefit of U.S. Provisional Patent Application No. 63/404,280, filed Sep. 7, 2020, titled “Electronic Circuit Packages,” which is incorporated by reference herein in its entirety.

### FIELD

This disclosure relates to electronic circuit packages and, more particularly, to flexible circuit packages.

### BACKGROUND

Electronic packages can include active devices, passive devices, and/or integrated circuits, which are mounted on printed circuit boards (PCBs). The PCBs can be classified into three categories based on their flexibility—e.g., rigid PCBs, flexible PCBs, and rigid-flex PCBs. The flexible PCBs can be thinner, more light weight, and more flexible than the rigid and rigid-flex PCBs. Space and height constraints for electronic circuit packaging can dictate the use of flexible PCBs over the rigid and rigid-flex PCBs. For example, the electronic circuit packages on flexible PCBs have been used in portable and mobile electronic devices with compact form factors, such as mobile phones, digital cameras, portable gaming devices, and other mobile devices.

### SUMMARY

Various embodiments of a flexible circuit package with a high-modulus molding compound layer are disclosed. In some embodiments, a structure includes a substrate with first and second regions. The first region is configured to bend. The structure further includes a conductive line disposed on the second region, an electronic component disposed on the conductive line, and a molding compound layer disposed on the second region and surrounding the electronic component. A modulus of the molding compound layer is greater than a modulus of the substrate and the molding compound layer is configured to prevent the second region from bending.

In some embodiments, a structure includes a substrate with first and second regions. The first region is configured to bend. The structure further includes a first conductive line disposed on a first surface of the second region and a second conductive line disposed on a second surface of the second region. The first and second surfaces are opposite to each other. The structure further includes a first electronic component disposed on the first conductive line, a second electronic component disposed on the second conductive line, a first molding compound layer disposed on the first surface of the second region and surrounding the first electronic component, and a second molding compound layer disposed on the second surface of the second region and surrounding the second electronic component. A first modulus of the first molding compound layer is greater than a modulus of the substrate and a second modulus of the second molding compound layer is greater than the modulus of the substrate.

In some embodiments, a method includes forming a conductive line on a first surface of a flexible substrate and mounting a rigid substrate on a second surface of the flexible substrate. The first and second surfaces are opposite to each other. The method further includes bonding an electronic component on the conductive line, forming a molding compound layer surrounding the electronic component, and removing the rigid substrate.

### BRIEF DESCRIPTION OF THE DRAWINGS

Aspects of this disclosure are best understood from the following detailed description when read with the accompanying figures.

FIGS. 1A-1B, 2A-2B, 3A-3B, and 4A-4B illustrate cross-sectional views of different flexible circuit packages with molding compound layers, in accordance with some embodiments.

FIG. 1C illustrates a cross-sectional view of an integrated circuit (IC) chip package, in accordance with some embodiments.

FIG. 5 is a flow diagram of a method for fabricating a flexible circuit package with molding compound layers, in accordance with some embodiments.

FIGS. 6-10 illustrate cross-sectional views of a flexible circuit package with molding compound layers at various stages of its fabrication process, in accordance with some embodiments.

FIG. 11 is a flow diagram of a method for fabricating another flexible circuit package with molding compound layers, in accordance with some embodiments.

FIGS. 12-15 illustrate cross-sectional views of another flexible circuit package with molding compound layers at various stages of its fabrication process, in accordance with some embodiments.

FIG. 16 illustrates exemplary systems or devices that can include the different flexible circuit packages with molding compound layers, in accordance with some embodiments.

Illustrative embodiments will now be described with reference to the accompanying drawings. In the drawings, like reference numerals generally indicate identical, functionally similar, and/or structurally similar elements. The discussion of elements with the same annotations applies to each other, unless mentioned otherwise.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

Electronic devices, such as computers, mobile phones, cameras, watches, and tablets contain electrical components, such as microprocessors, memory chips, integrated circuits, capacitors, resistors, inductors, and the like, which can be mounted on printed circuit substrates. Some of the printed circuit substrates can be flexible. The flexible printed circuit substrates can include flexible substrates formed with sheet(s) of a flexible polymer, such as polyimide. Conductive layers can be patterned on the flexible substrates to form conductive lines (e.g., metal traces) and bonding pads (e.g., solder pads) can be formed on the conductive lines. The bonding pads can be used to electrically connect the electrical components to the conductive lines, and thereby to other electrical components mounted on the flexible printed circuit substrate.

The flexible printed circuit substrate can be used for forming a flexible circuit package having flexible regions and component regions. The flexible regions can include first regions of the flexible substrate that can be bent and folded to accommodate the flexible circuit package in an electronic device housing. The component regions can include electrical components mounted on one side of second regions of the flexible substrate and encapsulation layers (e.g., epoxy-based layers) disposed conformally on the electronic components to protect them from moisture and handling damages. The component regions can further include stiffeners (also referred to as a “supporting place” or a “reinforcing plate”) mounted on the other side of the second regions and beneath the electrical components to increase the structural rigidity of the second regions. The stiffeners can be first bonded to the second regions with adhesives and then the electrical components can be surface mounted to the bonding pads on the stiffened second regions with bonding structures (e.g., solder balls). The encapsulating layers can then be formed individually on each of the surface mounted electrical components.

The stiffeners can increase the structural rigidity of the second regions to prevent warping of the second regions during the surface mounting and encapsulating of the electronic components. In addition, the stiffeners can provide mechanical support to the bonding interfaces (e.g., solder joints) between the surface mounted electrical components and the flexible printed circuit substrate. Furthermore, the stiffeners can locally inhibit the thermal expansion and shrinkage of the second regions during fabrication and functioning of the flexible circuit package. As a result, the stiffeners can reduce the stresses at the bonding interfaces and increase the reliability of the electrical connections between the surface mounted electrical components and the flexible printed circuit substrate.

However, the use of stiffeners adds to the size (e.g., height) and weight of the flexible circuit package and to the volume occupied by the flexible circuit package in the electronic device housing. In addition, the stiffeners occupy space on the flexible substrate that can be used for mounting electrical components. Thus, the continued miniaturization of electronic device to meet the increasing demand for smaller and more light-weight electronic devices increases the challenges of manufacturing flexible circuit packages with stiffeners that can meet the size and weight constraints of the electronic devices and/or that can meet the volume constraints of electronic device housings.

The present disclosure provides example flexible circuit packages formed with high-modulus molding compound layers and without stiffeners and encapsulation layers to reduce the size and weight of the flexible circuit packages. The present disclosure also provides examples methods of forming such smaller and lighter flexible circuit packages. In some embodiments, the flexible circuit package can include a flexible region and a molded region (also referred to as a “component region”). The flexible region can include a first region of a flexible substrate that can be bent and folded. The molded region can include (i) electrical components surface mounted on a first side of a second region of the flexible substrate and (ii) a molding compound layer with a high modulus (also referred to as a “high-modulus molding compound layer”) disposed on the first side of the second region and surrounding the electrical components. The term “modulus,” as used herein, refers to the flexural modulus (also referred to as “bending modulus”) of a material. The flexural modulus is a mechanical property of the material that indicates the material's stiffness or resistance to a bending action. The higher the flexural modulus of a material, the harder it is to bend. The term “high modulus,” as used herein, refers to the flexural modulus of a material greater than about 15 gigapascals (GPa) at a temperature of about 25° C.

Similar to the stiffeners, the molding compound layer can be configured to provide structural rigidity to the second regions of the flexible substrate to prevent any substantial bending of the second regions during the handling and usage of the flexible circuit package. The molding compound layer can also be configured to provide mechanical support to the bonding interfaces between the electrical components and the flexible printed circuit substrate and to reduce or substantially minimize the thermal stresses induced at the bonding interfaces during the fabrication and functioning of the flexible circuit package. In addition, similar to the encapsulating layers, the molding compound layer can be configured to protect the electrical components from moisture and handling damages. Since the molding compound layer can serve the functions of both the stiffeners and the encapsulating layers, the molding compound layer can replace the use of stiffeners and encapsulation layers in flexible circuit packages. As a result, the flexible circuit package formed with the high-modulus molding compound layer can have a thinner profile and a lighter weight than flexible circuit packages formed with stiffeners and encapsulation layers, while maintaining its structural and mechanical integrity. In some embodiments, a thickness (or height) of the flexible circuit package formed with the high-modulus molding compound layer can be about 0.25 mm to about 0.5 mm less than that of flexible circuit packages formed with stiffeners or can be reduced by about 10% to about 50% compared to flexible circuit packages formed with stiffeners. Furthermore, eliminating the use of stiffeners in flexible circuit packages can increase the surface area for mounting electronic components without increasing the package size, thus increasing the device density and performance of the flexible circuit packages.

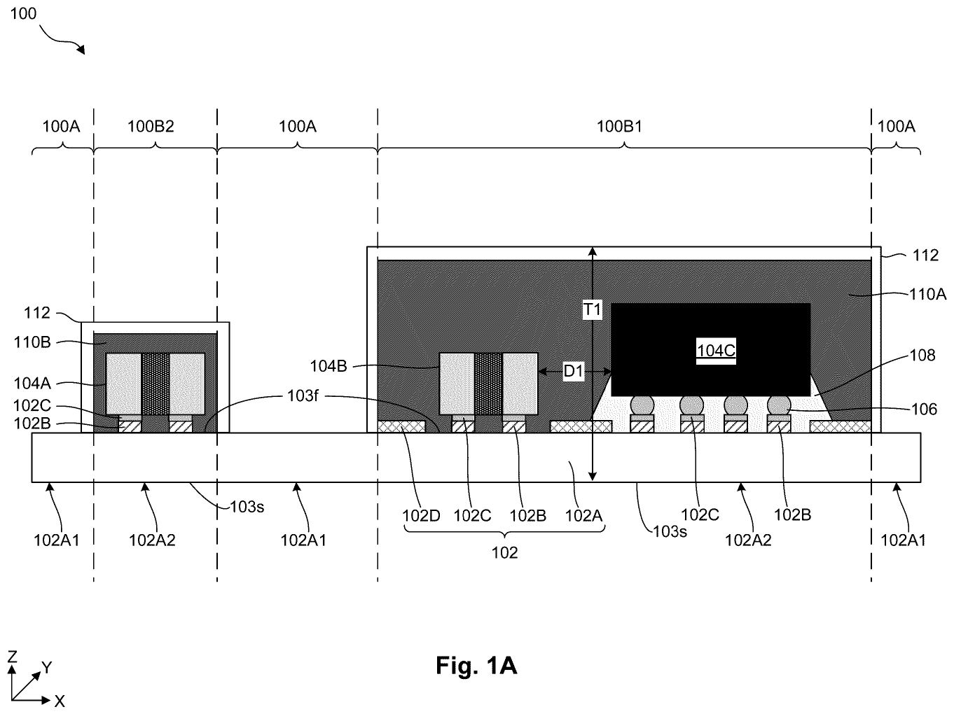

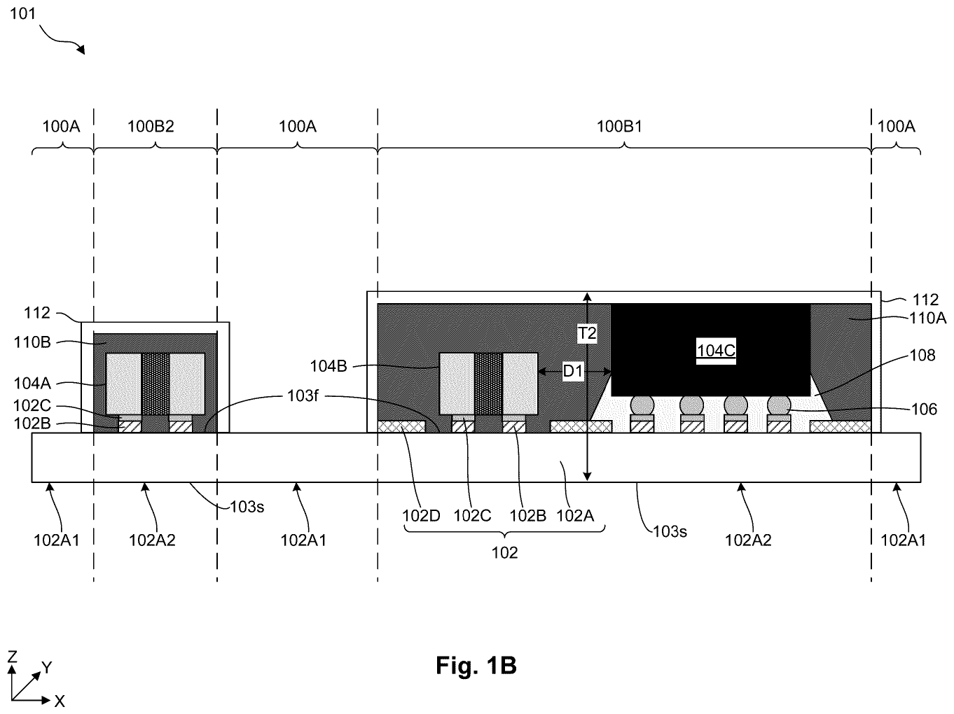

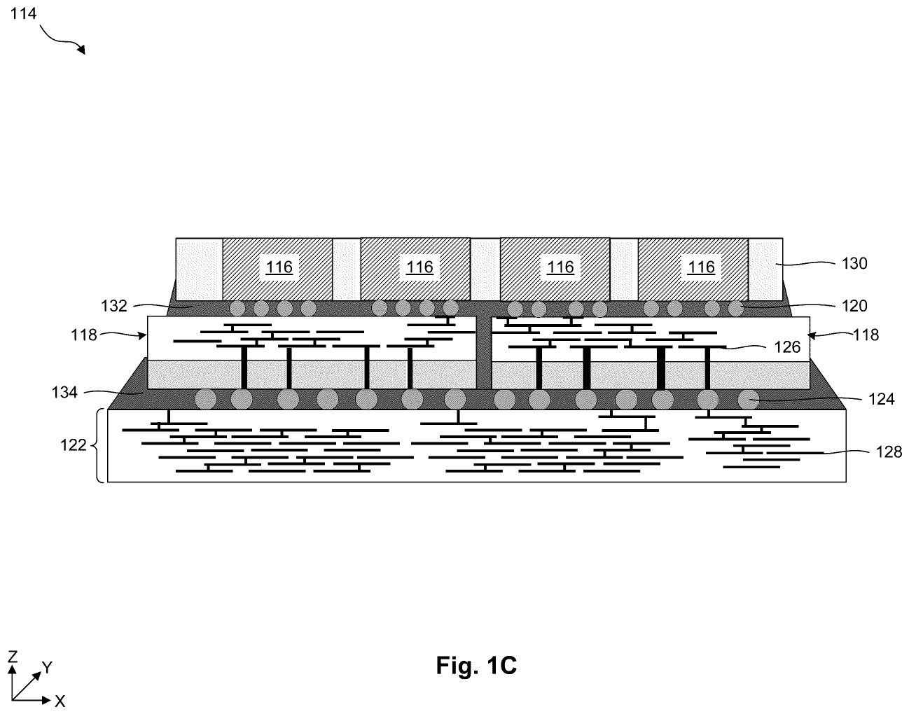

FIG. 1A illustrates a cross-sectional view of a flexible circuit package 100, according to some embodiments. In some embodiments, flexible circuit package 100 can be divided into flexible regions 100A and molded regions 100B1 and 110B2 (also referred to as “component regions 100B1 and 100B2”). In some embodiments, flexible circuit package 100 can include (i) a flexible printed circuit substrate 102, (ii) electronic components 104A, 104B, and 104C, (iii) conductive bonding structures 106, (iv) an underfill layer 108, (v) molding compound layers 110A and 110B, and (vi) shielding layers 112. In some embodiments, flexible printed circuit substrate 102 can include (i) a flexible substrate 102A, (ii) conductive lines 102B, (iii) conductive pads 102C, and (iv) masking layers 102D.

In some embodiments, each of flexible regions 100A can include a first region 102A1 of flexible substrate 102A that can be bent and folded to accommodate and adjust flexible circuit package 100 within the confines of an electronic device housing. To promote bending and folding of flexible regions 100A, first regions 102A1 can be kept free of electronic components, such as electronic components 104A, 104B, and/or 104C on first region 102A1. In some embodiments, to promote bending and folding of flexible regions 100A, first regions 102A1 can be kept free of conductive lines 102B, conductive pads 102C, and/or masking layers 102D.

Molded regions 100B1 and 100B2 can be separated from each other and from other adjacent molded regions (not shown) by flexible regions 100A. Each of molded regions 100B1 and 100B2 can be configured to be substantially non-flexible and/or to be substantially resistant to warping and/or any bending action, which is described in detail below. In some embodiments, molded region 100B1 can include (i) a second region 102A2 of flexible substrate 102A, (ii) conductive lines 102B, (iii) conductive pads 102C, (iv) masking layers 102D, (v) electronic components 104B and 104C, (vi) conductive bonding structures 106, (vii) underfill layer 108, (viii) molding compound layer 110A, and (ix) shielding layer 112. In some embodiments, molded region 100B2 can include (i) second region 102A2, (ii) conductive lines 102B, (iii) conductive pads 102C, (iv) electronic component 104C, (v) molding compound layer 110B, and (vi) shielding layer 112. Though two molded regions 100B1 and 100B2 are shown in FIG. 1A, flexible circuit package 100 can include any number of molded regions. The number and type of electronic components shown in molded regions 100B1 and 100B2 are exemplary and not limiting. Molded regions 100B1 and 100B2 can include any number and any type of electronic components.

In some embodiments, flexible substrate 102A can include one or more layers of dielectric material that facilitate bending of flexible substrate 102A at a bending angle between about 0 degree and about 180 degrees with respect to an X-axis. In some embodiments, the dielectric material can include polyimide or any other suitable flexible polymeric material. In some embodiments, conductive lines 102B can be disposed on first sides 103f (also referred to as “front-sides 103f”) of second regions 102A2 and can provide electrical connection paths between electronic components, such as electronic components 104A, 104B, and/or 104C on second regions 102A2. In some embodiments, conductive lines 102B can include patterned metal lines (also referred to as “metal traces”). In some embodiments, the metal lines can include a metal, such as copper, nickel, aluminum, gold, and other suitable metals or can include a metal alloy, such as copper alloys, nickel alloys, aluminum alloys, gold alloys, or other suitable metal alloys.

In some embodiments, some top surfaces of conductive lines 102B can be covered (not shown) with insulating layers, such as masking layers 102D (also referred to as “solder masks 102D”) and some top surfaces of conductive lines 102B can be free of the insulating layers to provide electrical contact areas for making electrical connections with electronic components 104A, 104B, and/or 104C, as shown in FIG. 1A. In some embodiments, masking layers 102D can include an epoxy-based material. Conductive pads 102C can be disposed on the top surfaces of conductive lines 102B that are free of masking layers 102D and can serve as bonding pads for bonding electronic components 104A, 104B, and/or 104C with conductive lines 102B. In some embodiments, conductive pads 102C can include solder paste.

In some embodiments, electronic components 104A, 104B, and 104C can be electrically and mechanically bonded (e.g., solder bonded) to conductive lines 102B with surface mount technology (SMT). In some embodiments, electronic components 104A and 104B can include passive components, such as resistors, capacitors, inductors diodes, and other passive devices. The terminals or leads of electronic components 104A and 104B can be solder bonded to conductive lines 102B through conductive pads 102C.

In some embodiments, electronic component 104C can include an IC chip package 114 implemented in a multi-chip-module (MCM) arrangement, as shown in FIG. 1C. In some embodiments, IC chip package 114 can include IC chips 116 disposed on and electrically connected to interconnect substrates 118 (e.g., interposers 118) through conductive bonding structures 120 (e.g., solder bumps). Each of interconnect substrates 118 can be disposed on and electrically connected to package substrate 122 through conductive bonding structures 124 (e.g., solder bumps). Interconnect substrates 118 can include conductive lines 126 that are electrically connected to conductive bonding structures 120. Package substrate 122 can include conductive lines 128 that are electrically connected to conductive bonding structures 124 on one side and to conductive bonding structures 106 on the other side. Thus, IC chips 116 can be electrically connected to conductive lines 102B (shown in FIG. 1A) through interconnect substrates 118 and package substrate 122 and electrical signals between IC chips 116 and electronic components mounted on flexible printed circuit substrate 102 (shown in FIG. 1A) can be transmitted through conductive lines 102B, 126, and 128. In some embodiments, IC chip package 114 can include encapsulating layer 130 surrounding IC chips 116 and underfill layers 132 and 134.

Referring to FIGS. 1A and 1C, in some embodiments, electronic component 104C can include IC chip package 114, which can be bonded to conductive lines 102B using a flip-chip bonding configuration (shown in FIG. 1A) or other suitable bonding configurations. In the flip-chip bonding configuration, IC chip package 114 can be electrically bonded (e.g., solder bonded) to conductive pads 102C (shown in FIG. 1A) using conductive bonding structures 106 (e.g., solder bumps 106; shown in FIG. 1A). In some embodiments, electronic component 104C can include an IC chip, such as IC chip 116 instead of IC chip package 114 and conductive bonding structures 106 (shown in FIG. 1A) can be formed on the IC chip. The IC chip can be directly solder bonded to conductive pads 102C using conductive bonding structures 106.

Referring to FIG. 1A, in some embodiments, underfill layer 108 can be disposed in the spaces between electronic component 104C and flexible substrate 102A that are unoccupied by conductive lines 102B, conductive pads 102C and conductive bonding structures 106. Underfill layer 106 can surround conductive bonding structures 106 and conductive pads 102C and can provide mechanical support to the bonding interfaces (e.g., solder joints) between electronic component 104C and flexible substrate 102A. The mechanical support can mitigate and distribute the thermal stresses induced at the bonding interfaces during the operation of electronic component 104C due to the thermal expansion coefficient mismatch between electronic component 104C and flexible substrate 102A. In some embodiments, underfill layer 108 can include a polymeric material, such as an epoxy-based material.

Molding compound layers 110A and 110B can surround electronic components 104A, 104B, and 104C and can be disposed on second regions 102A2. In some embodiments, molding compound layers 110A and 110B can extend above the top surfaces of electronic components 104A, 104B, and 104C. In some embodiments, molding compound layers 110A and 110B can be configured to provide localized structural rigidity to second regions 102A2 of flexible substrate 102A. In other words, molding compound layers 110A and 110B can be configured such that the adhesion of molding compound layers 110A and 110B to second regions 102A2 can promote a localized stiffening effect (or bending resistance) in second regions 102A2. The localized structural rigidity and stiffening effect can be provided by molding compound layers 110A and 110B to prevent any substantial bending and/or warping of second regions 102A2 during the handling and usage of flexible circuit package 100. For example, molding compound layers 110A and 110B can prevent second regions 102A2 from bending more than about 0.5 degrees to about 5 degrees with respect to an X-axis. Preventing such substantial bending and/or warping of second regions 102A2 can minimize mechanical and/or thermal stresses at the bonding interfaces (e.g., solder joints) between flexible substrate 102A and electronic components 104A, 104B, and 104C, thus increasing the reliability and durability of the electrical connections and mechanical bonds between electrical components 104A, 104B, and 104C and flexible substrate 102A.

To promote the localized stiffening effect or bending resistance in second regions 102A2, each of molding compound layers 110A and 110B can include a modulus greater than that of flexible substrate 102A and/or a thermal expansion coefficient smaller than that of flexible substrate 102A. In some embodiments, each of molding compound layers 110A and 110B can have (i) a modulus greater than about 15 GPa at a temperature of about 25° C. (e.g., a modulus between about 15 GPa and about 60 GPa), (ii) a modulus greater than about 0.2 GPa at a temperature of about 260° C. (e.g., a modulus between about 0.2 GPa and about 10 GPa), (iii) a flexural strength of about 100 MPa to about 160 MPa at a temperature of about 25° C., (iv) a flexural strength of about 5 MPa to about 15 MPa at a temperature of about 260° C., (v) a glass transition temperature (Tg) greater than about 120° C. (e.g., a Tg between about 120° C. and about 400° C.), (vi) thermal expansion coefficients α1 of about 5×10⁻⁶ to about 20×10¹⁰ parts per million (ppm)/° C. and α2 of about 40×10⁻⁶ to about 80×10¹⁰ ppm/° C., (vii) a water absorption of about 0.05% weight by weight (w/w) to about 0.15% w/w in a pressure cook test (PCT), and (viii) a water absorption of about 0.1% w/w to about 0.25% w/w in a 24 hr boiling water test. With the above-mentioned physical and mechanical properties, molding compound layers 110A and 110B can adequately prevent any substantial bending and/or warping of second regions 102A2 during the handling and usage of flexible circuit package 100. In some embodiments, each of molding compound layers 110A and 110B can include a polymer-based material or any other suitable material with the above-mentioned physical and mechanical properties.

The use of molding compound layers 110A and 110B can eliminate the use of stiffeners on second side 103s (also referred to as “back-sides 103s”) of second regions 102A2 for providing structural rigidity to second regions 102A2. As a result, flexible circuit package 100 can have a thinner profile along a Z-axis than that of flexible circuit packages formed with stiffeners. In some embodiments, a thickness (or height) of flexible circuit package 100 along a Z-axis can be about 0.25 mm to about 0.5 mm less than that of flexible circuit packages formed with stiffeners or can be reduced by about 10% to about 50% compared to flexible circuit packages formed with stiffeners. Furthermore, eliminating the use of stiffeners can increase the manufacturing yield of flexible circuit packages similar to flexible circuit package 100 as there is no yield loss due to misalignments between stiffeners and electronic components in the flexible circuit packages.

In addition, the use of molding compound layers 110A and 110B can eliminate the use of individual protection layers for electrical components 104A, 104B, and 104C as molding compound layers 110A and 110B can protect electrical components 104A, 104B, and 104C from moisture and handling damages. In some embodiments, the substantially linear top surface and sidewall profiles of molding compound layers 110A and 110B can provide functional surfaces for aligning other components with and/or mounting other components on flexible circuit package 100 in an electronic device housing. In some embodiments, the linear top surface and sidewall profiles of molding compound layers 110A and 110B can facilitate the formation of substantially conformal shielding layers 112 on molding compound layers 110A and 110B for shielding electrical components 104A, 104B, and 104C from electromagnetic interference (EMI). The use of such conformal shielding layers 112 can eliminate the use of separate metal covers encasing electronic components in flexible circuit packages that adds height and weight to the flexible circuit packages. Thus, flexible circuit package 100 can have a thinner profile and lighter weight than that of flexible circuit packages using metal covers for EMI shielding. In some embodiments, shielding layers 112 can include a metallic material. In some embodiments, flexible circuit package 100 can be formed without shielding layers 112.

FIG. 1B illustrates a cross-sectional view of a flexible circuit package 101, according to some embodiments. The discussion of flexible circuit package 100 applies to flexible circuit package 101, unless mentioned otherwise. The discussion of elements in FIGS. 1A and 1B with the same annotations applies to each other, unless mentioned otherwise. In some embodiments, molding compound layer 110A can be formed substantially coplanar with the top surface of electronic component 104C to form flexible circuit package 101 with a thickness T2 that is smaller than a thickness T1 of flexible circuit package 100.

In some embodiments, a molding compound layer, similar to molding compound layer 110A can be disposed on first region 102A1 of flexible substrate 102A.

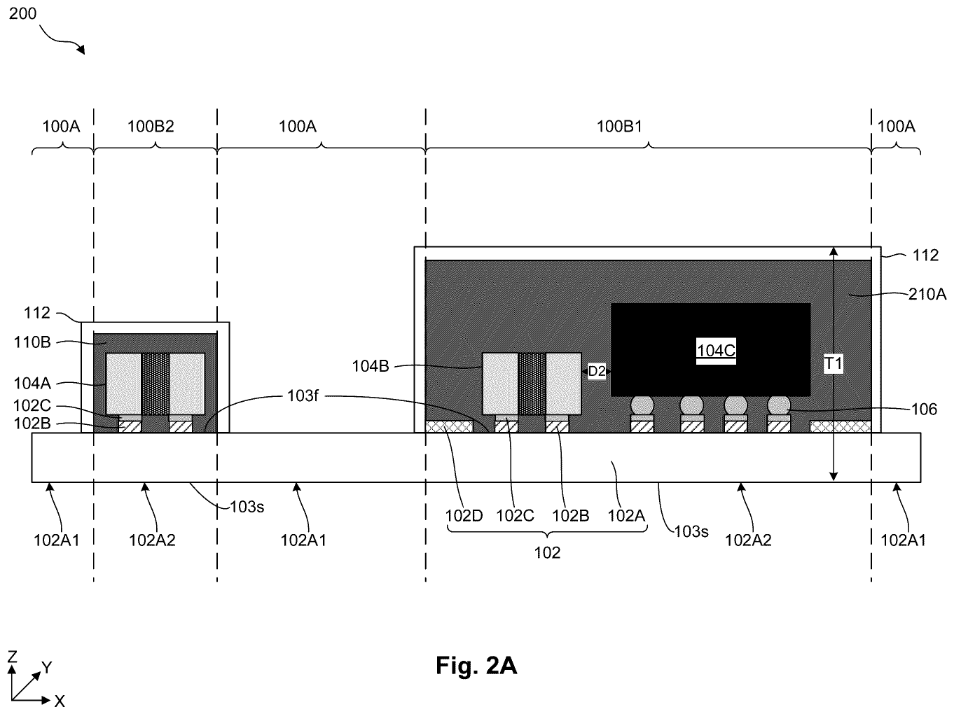

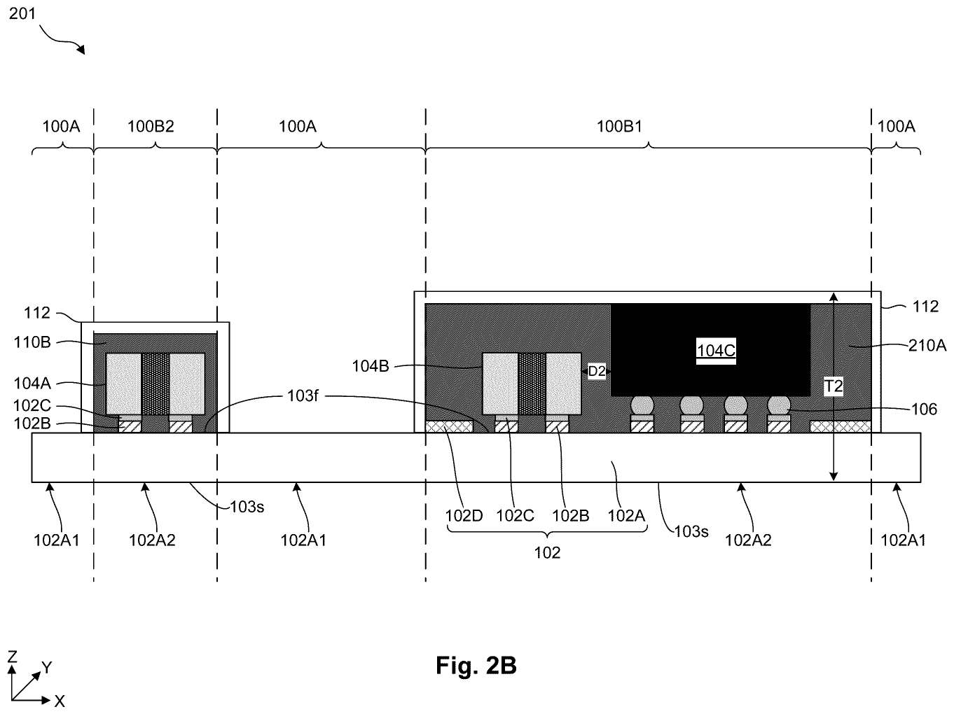

FIG. 2A illustrates a cross-sectional view of a flexible circuit package 200, according to some embodiments. The discussion of flexible circuit package 100 applies to flexible circuit package 200, unless mentioned otherwise. The discussion of elements in FIGS. 1A and 2A with the same annotations applies to each other, unless mentioned otherwise. In some embodiments, flexible circuit package 200 can include a molding compound layer 210A, instead of molding compound layer 110A. The discussion of molding compounding layer 110A applies to molding compound layer 210A, unless mentioned otherwise. In some embodiments, molding compounding layer 210A can replace the use of underfill layer 108, as discussed above with reference to FIG. 1A. Molding compound layer 210A can be disposed to surround conductive bonding structures 106 and conductive pads 102C, instead of underfill layer 108 shown in FIG. 1A. Molding compound layer 210A can be configured to provide mechanical support to the bonding interfaces (e.g., solder joints) between electronic component 104C and flexible substrate 102A and to reduce or substantially minimize the thermal stresses induced at the bonding interfaces during the handling and functioning of the flexible circuit package.

In some embodiments, by replacing underfill layer 108 with molding compound layer 210A, the processing time and cost for fabricating flexible circuit package 200 can be reduced compared to flexible circuit package 100. Moreover, by replacing underfill layer 108 with molding compound layer 210A, the space constraints between electronic components can be reduced. In other words, electronic components 104B and 104C can be placed closer to each other by replacing underfill layer 108 with molding compound layer 210A because the surface area of second regions 102A2 occupied by the tapered sidewalls of underfill layer 108 can be available for mounting electronic components 104B and/or 104C. In some embodiments, by replacing underfill layer 108 with molding compound layer 210A, electronic components 104B and 104C in flexible circuit package 200 can be spaced apart from each other by a distance D2 that is shorter than distance D1 between electronic components 104B and 104C in flexible circuit package 100. Thus, the density of electronic components can be increased in flexible circuit package 200 and/or a more compact sized flexible circuit package 200 can be formed by using molding compound layer 210A.

FIG. 2B illustrates a cross-sectional view of a flexible circuit package 201, according to some embodiments. The discussion of flexible circuit package 200 applies to flexible circuit package 201, unless mentioned otherwise. The discussion of elements in FIGS. 2A and 2B with the same annotations applies to each other, unless mentioned otherwise. In some embodiments, molding compound layer 210A can be formed substantially coplanar with the top surface of electronic component 104C to form flexible circuit package 201 with a thickness T2 that is smaller than a thickness T1 of flexible circuit package 200.

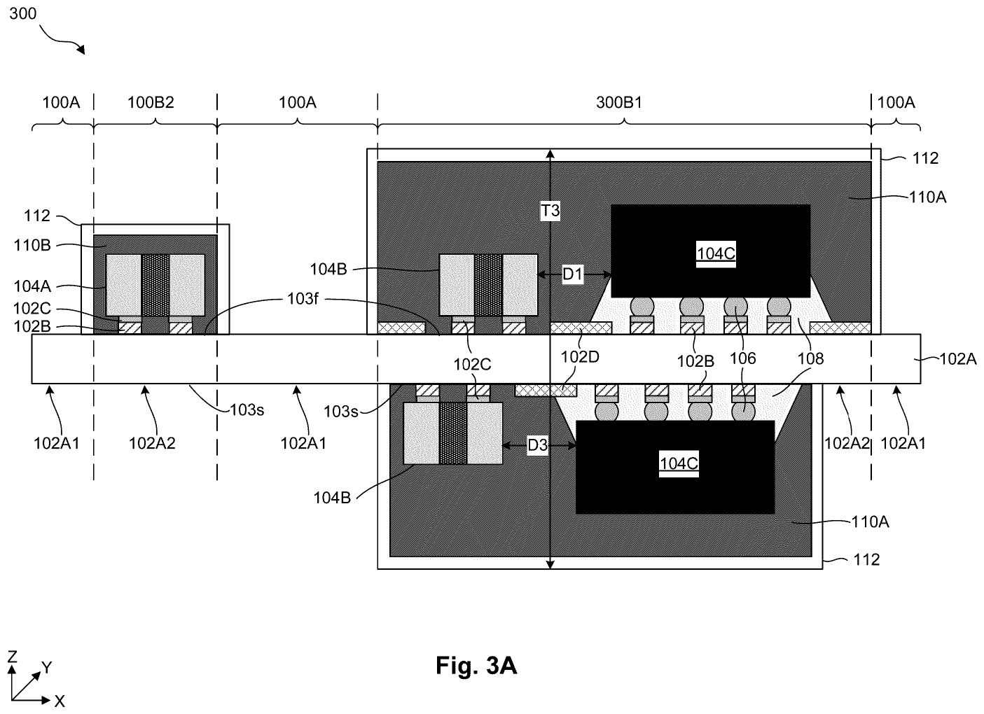

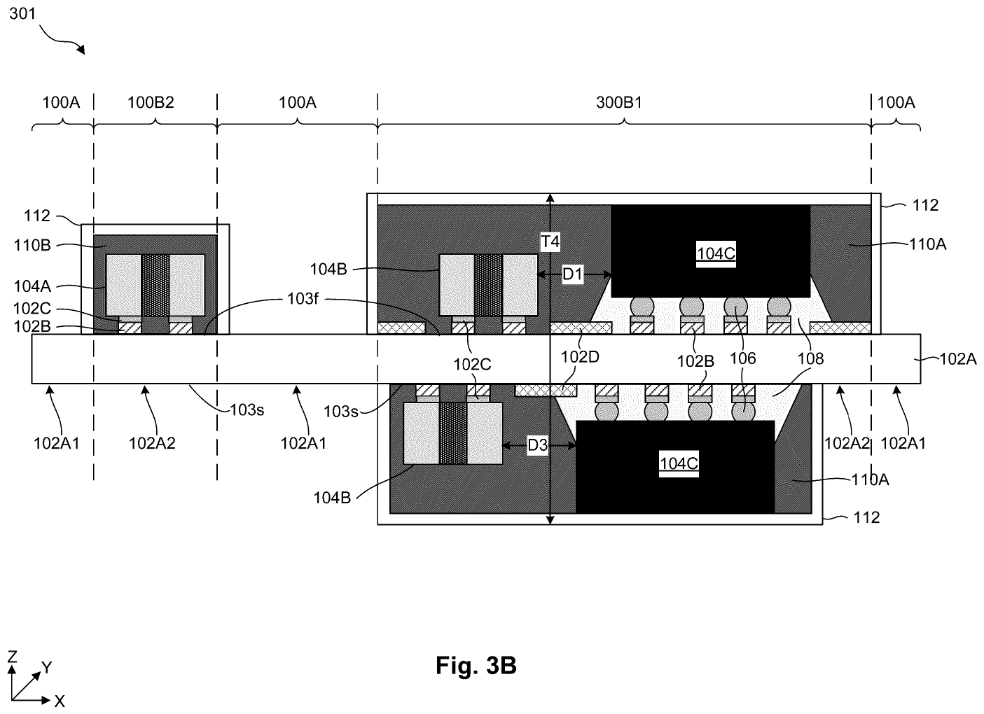

FIG. 3A illustrates a cross-sectional view of a flexible circuit package 300, according to some embodiments. The discussion of flexible circuit package 100 applies to flexible circuit package 300, unless mentioned otherwise. The discussion of elements in FIGS. 1A and 3A with the same annotations applies to each other, unless mentioned otherwise. As discussed above, the use of molding compound layer 110A can eliminate the use of stiffeners on second side 103s of second regions 102A2, which makes additional surface area available on flexible substrate 102A for mounting additional electronic components. For example, additional electronic components 104B and 104C can be surface mounted on second side 103s of second regions 102A2 to form flexible circuit package 300.

In some embodiments, flexible circuit package 300 can include a molded region 300B1, instead of molded region 100B1. In some embodiments, compared to molded region 100B1, molded region 300B1 can include additional (i) conductive lines 102B, (ii) conductive pads 102C, (iii) masking layers 102D, (iv) electronic components 104B and 104C, (v) conductive bonding structures 106, (vi) underfill layer 108, (vii) molding compound layer 110A, and (viii) shielding layer 312 disposed on second side 103s, which is opposite to first side 103f.

FIG. 3B illustrates a cross-sectional view of a flexible circuit package 301, according to some embodiments. The discussion of flexible circuit package 300 applies to flexible circuit package 301, unless mentioned otherwise. The discussion of elements in FIGS. 3A and 3B with the same annotations applies to each other, unless mentioned otherwise. In some embodiments, molding compound layers 110A can be formed substantially coplanar with the top surfaces of electronic components 104C to form flexible circuit package 301 with a thickness T4 that is smaller than a thickness T3 of flexible circuit package 300.

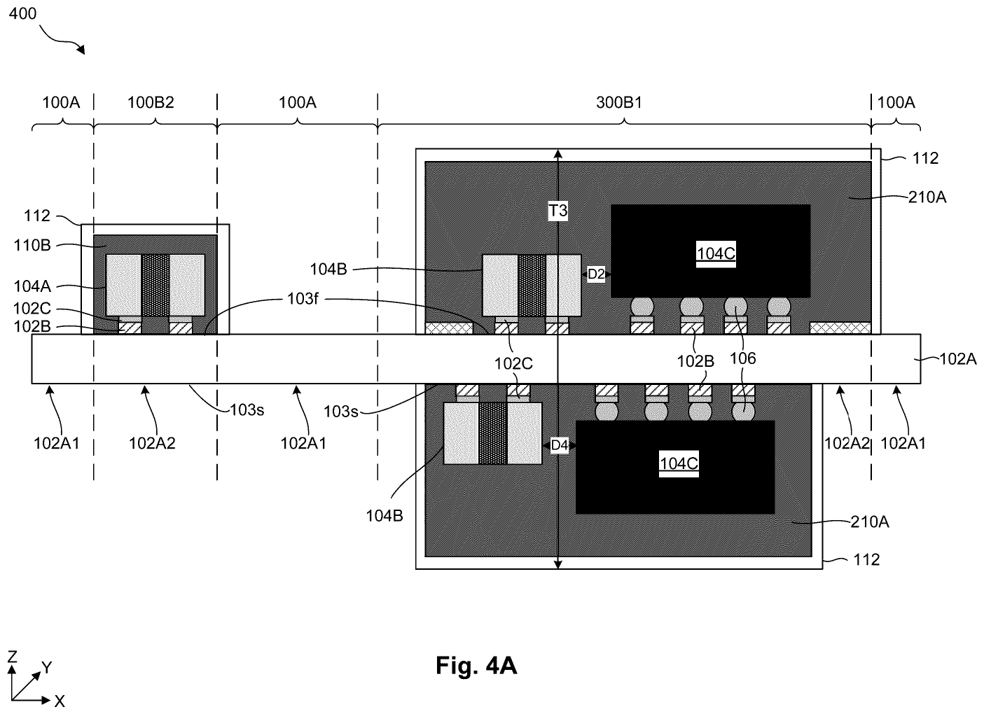

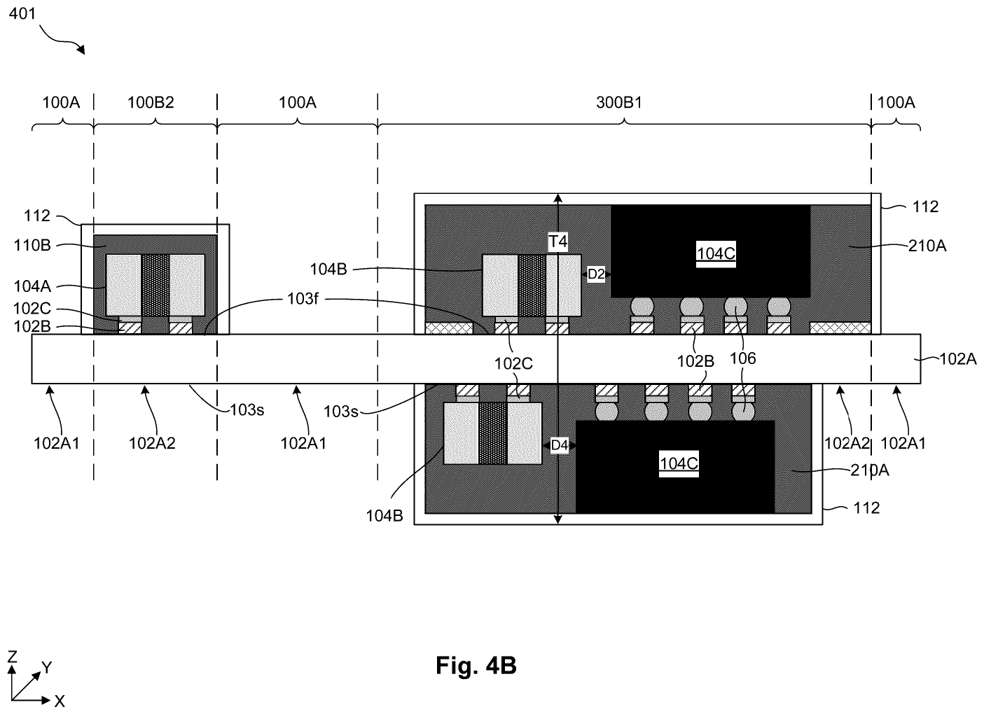

FIG. 4A illustrates a cross-sectional view of a flexible circuit package 400, according to some embodiments. The discussion of flexible circuit package 300 applies to flexible circuit package 400, unless mentioned otherwise. The discussion of elements in FIGS. 1A, 2A, 3A, and 4A with the same annotations applies to each other, unless mentioned otherwise. In some embodiments, flexible circuit package 400 can include molding compound layers 210A disposed on first side 103f and second side 103s, instead of molding compound layers 110A and underfill layers 108 shown in FIG. 3A. As discussed above with reference to FIG. 2A, by replacing underfill layers 108 with molding compound layers 210A, electronic components 104B and 104C in flexible circuit package 400 can be spaced apart from each other by distances D2 and D4 that are shorter than distances D1 and D3 between electronic components 104B and 104C in flexible circuit package 300.

FIG. 4B illustrates a cross-sectional view of a flexible circuit package 401, according to some embodiments. The discussion of flexible circuit package 400 applies to flexible circuit package 401, unless mentioned otherwise. The discussion of elements in FIGS. 4A and 4B with the same annotations applies to each other, unless mentioned otherwise. In some embodiments, molding compound layers 210A can be formed substantially coplanar with the top surfaces of electronic components 104C to form flexible circuit package 401 with a thickness T4 that is smaller than a thickness T3 of flexible circuit package 400.

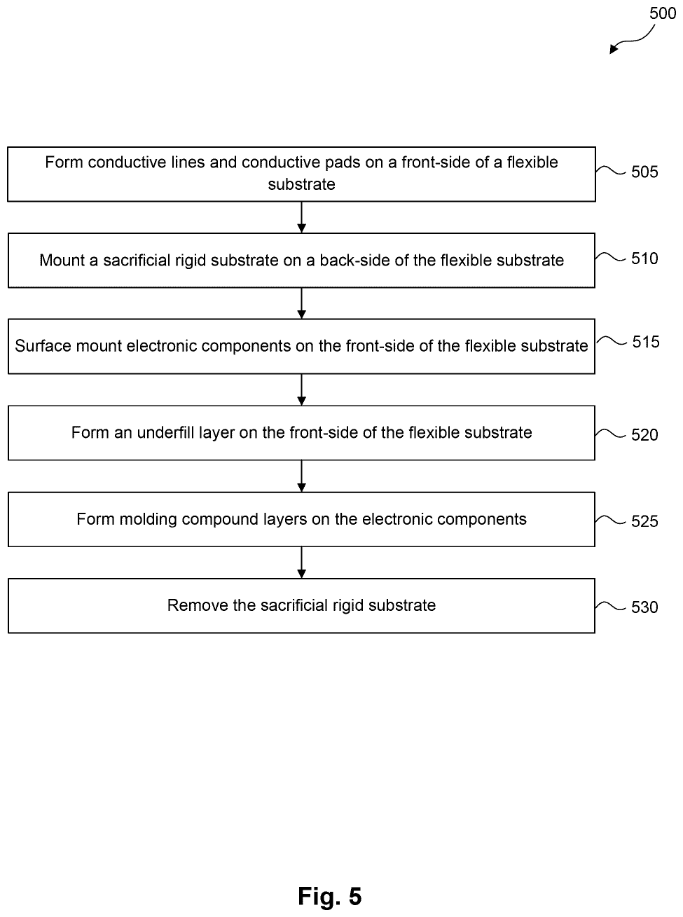

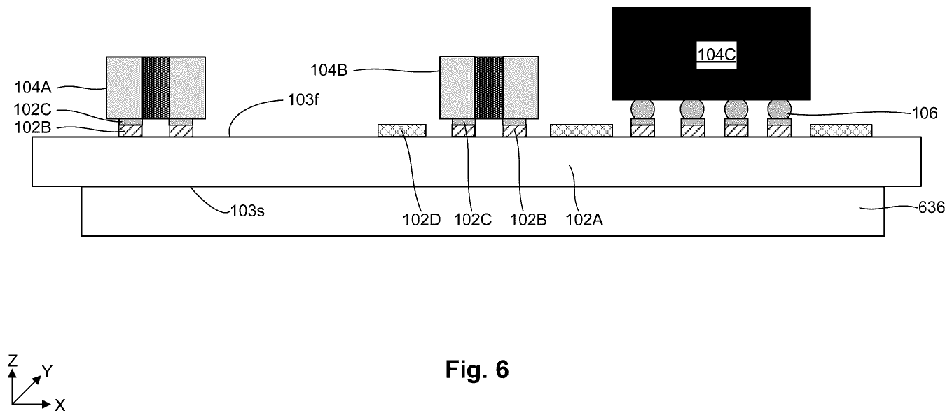

FIG. 5 is a flow diagram of an example method 500 for fabricating flexible circuit packages 100, 101, 200, and 201 shown in FIGS. 1A, 1B, 2A, and 2B, respectively, according to some embodiments. For illustrative purposes, the operations illustrated in FIG. 5 will be described with reference to the example fabrication process for fabricating flexible circuit packages 100, 101, 200, and 201 as illustrated in FIGS. 6-10. FIGS. 6-10 are cross-sectional views of flexible circuit packages 100, 101, 200, and 201 at various stages of fabrication, according to some embodiments. Operations can be performed in a different order or not performed depending on specific applications. It should be noted that method 500 may not produce a complete flexible circuit package 100, 101, 200, and/or 201. Accordingly, it is understood that additional processes can be provided before, during, and after method 500, and that some other processes may only be briefly described herein. Elements in FIGS. 6-10 with the same annotations as elements in FIGS. 1A-1B and 2A-2B are described above.

Referring to FIG. 5, in operation 505, conductive lines and conductive pads are formed on a front-side of a flexible substrate. For example, as shown in FIG. 6, conductive lines 102B and conductive pads 102C are formed on front-side 103f of flexible substrate 102A. In some embodiments, conductive lines 102B can be formed by depositing a metal layer (not shown) on front-side 103f of flexible substrate 102A, followed by patterning and etching of the deposited metal layer using a lithographic process. In some embodiments, conductive pads 102C can be formed by depositing solder paste on selective areas of conductive lines 102B.

Referring to FIG. 5, in operation 510, a sacrificial rigid substrate is mounted on a back-side of the flexible substrate. For example, as shown in FIG. 6, a sacrificial rigid substrate 636 is mounted on back-side 103s of flexible substrate 102A. In some embodiments, sacrificial rigid substrate 636 can include stainless steel, tungsten, or any other suitable rigid material. Sacrificial rigid substrate 636 can provide structural rigidity to flexible substrate 102A and can maintain front-side 103f of flexible substrate 102A substantially flat during the fabrication of flexible circuit packages 100, 101, 200, and 201. By maintaining front-side 103f of flexible substrate 102A substantially flat, the subsequent operations of surface mounting electronic components 104A, 104B, and 104C, forming underfill layer 108, and/or forming molding compound layers 110A and 110B on flexible substrate 102A can be adequately performed.

Referring to FIG. 5, in operation 515, electronic components are surface mounted on the front-side of the flexible substrate. For example, as shown in FIG. 6, electronic components 104A, 104B, and 104C are surface mounted on front-side 103f of flexible substrate 102A. In some embodiments, the surface mounting of electronic components 104A, 104B, and 104C can include placing the terminal of electronic components 104A and 104B and bonding structures 106 of electronic component 104C on conductive pads 102C, followed by performing a solder reflow process to form solder bonds between conductive lines 102B and electronic components 104A, 104B, and 104C.

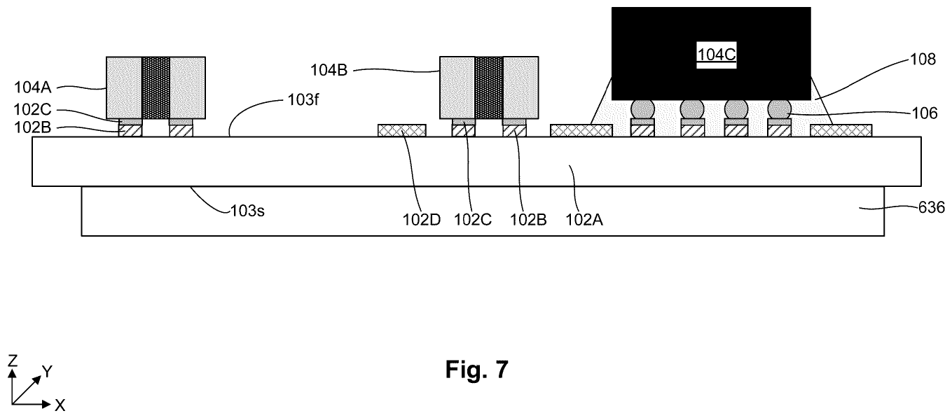

Referring to FIG. 5, in operation 520, an underfill layer is formed on the front-side of the flexible substrate. For example, as shown in FIG. 7, underfill layer 108 is formed on front-side 103f of flexible substrate 102A. In some embodiments, underfill layer 108 can be formed by dispensing and curing underfill material in the gaps between electronic component 104C and front-side 103f of flexible substrate 102A.

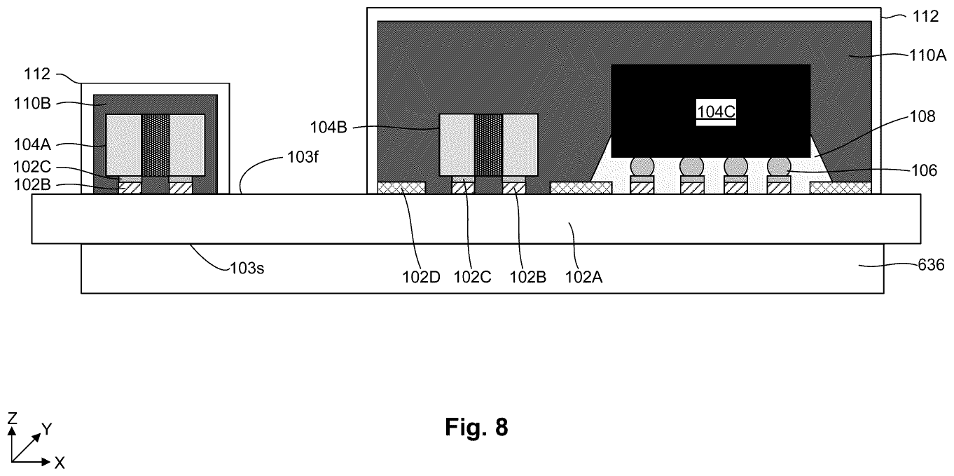

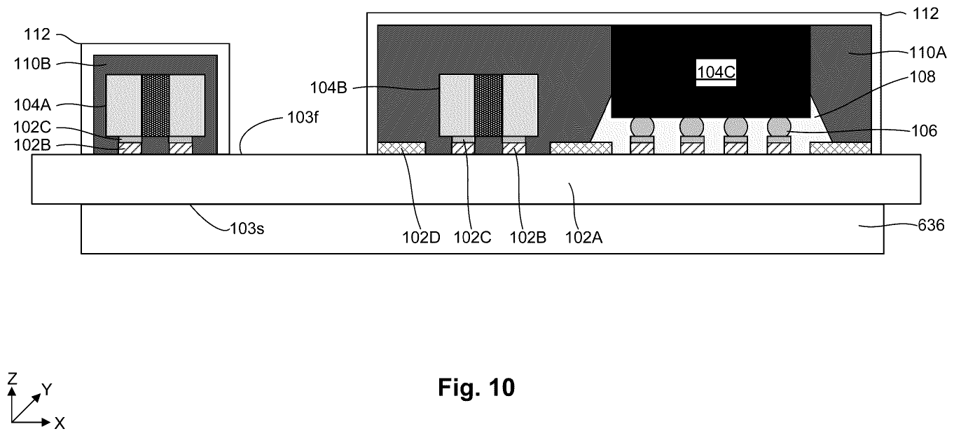

Referring to FIG. 5, in operation 525, molding compound layers are formed on the electronic components. For example, as shown in FIG. 8, molding compound layer 110A is formed on electronic components 104B and 104C, and molding compound layer 110B is formed on electronic component 104A. In some embodiments, after the formation of molding compound layers 110A and 110B, shielding layers 112 can be deposited on molding compound layers 110A and 110B. In some embodiments, prior to forming shielding layers 112, a chemical mechanical polishing (CMP) process can be performed on molding compound layer 110 to form the structure of FIG. 10.

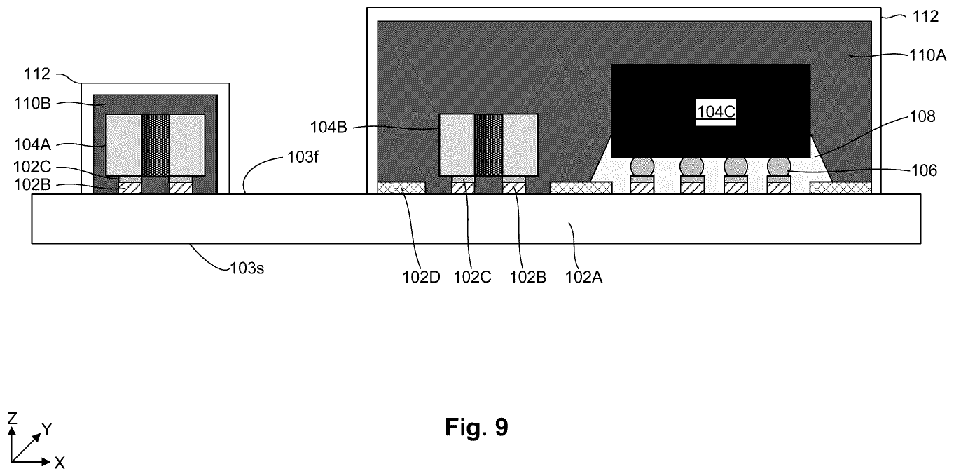

Referring to FIG. 5, in operation 530, the sacrificial rigid substrate is removed. For example, as shown in FIG. 9, sacrificial rigid substrate 636 is removed from the structure of FIG. 8 to form flexible circuit package 100 or from the structure of FIG. 10 to form flexible circuit package 101. In some embodiments, sacrificial rigid substrate 636 can be removed prior to forming shielding layers 112.

In some embodiments, the above discussion of forming flexible circuit packages 100 and 101 applies to the formation of flexible circuit packages 200 and 201 shown in FIGS. 2A and 2B, respectively, except operation 515 is followed by operation 525 to eliminate the formation of underfill layers 108 in flexible circuit packages 200 and 201.

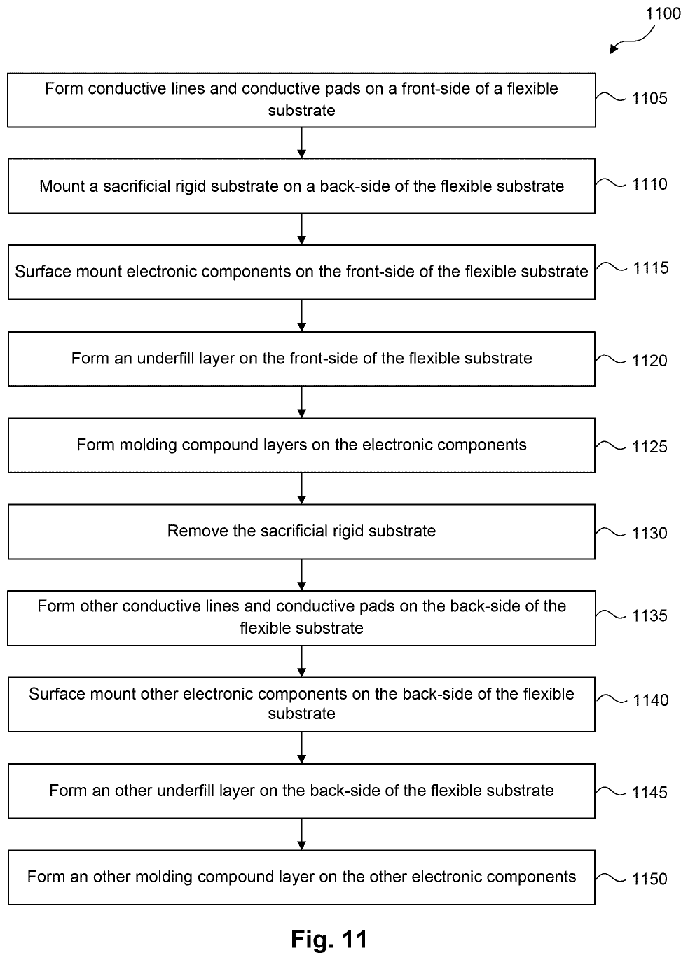

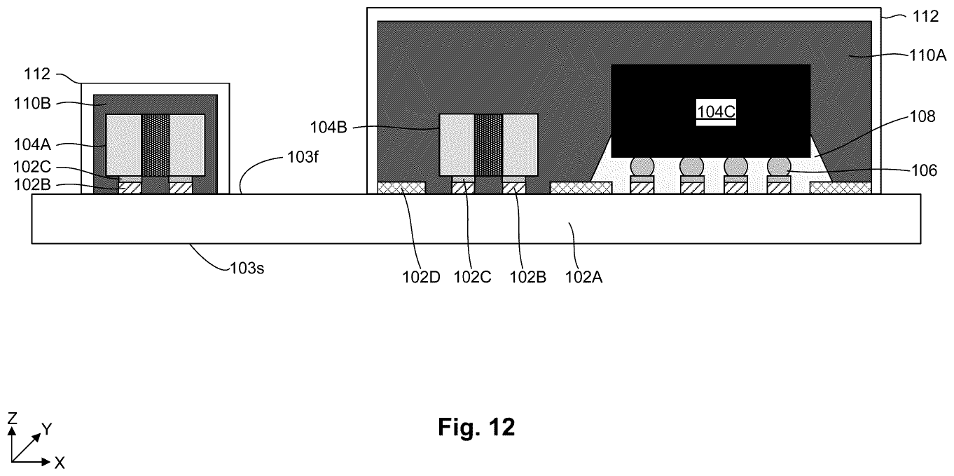

FIG. 11 is a flow diagram of an example method 1100 for fabricating flexible circuit packages 300, 301, 400, and 401 shown in FIGS. 3A, 3B, 4A, and 4B, respectively, according to some embodiments. For illustrative purposes, the operations illustrated in FIG. 11 will be described with reference to the example fabrication process for fabricating flexible circuit packages 300, 301, 400, and 401 as illustrated in FIGS. 12-15. FIGS. 12-15 are cross-sectional views of flexible circuit packages 300, 301, 400, and 401 at various stages of fabrication, according to some embodiments. Operations can be performed in a different order or not performed depending on specific applications. It should be noted that method 1100 may not produce a complete flexible circuit package 300, 301, 400, and/or 401. Accordingly, it is understood that additional processes can be provided before, during, and after method 1100, and that some other processes may only be briefly described herein. Elements in FIGS. 12-15 with the same annotations as elements in FIGS. 1A-1B, 2A-2B, 3A-3B, and 4A-4B are described above.

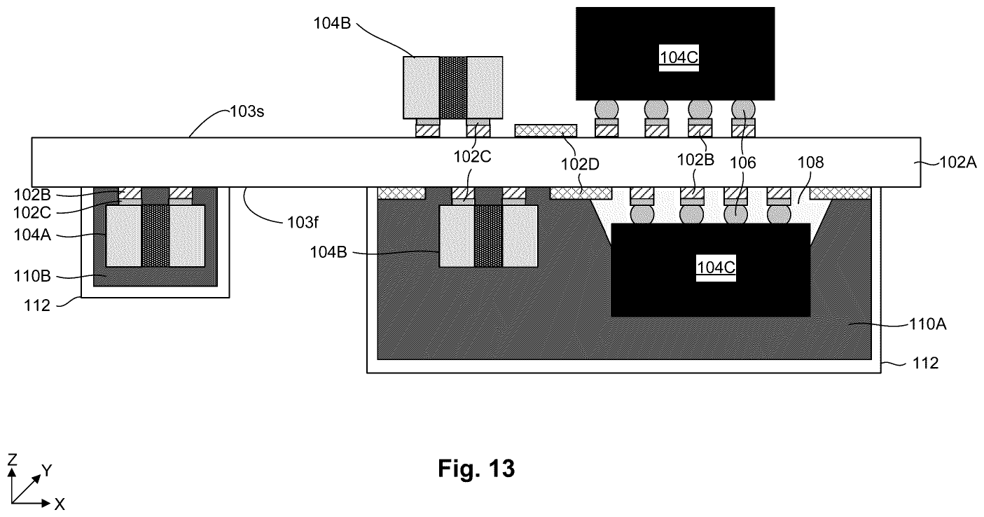

Referring to FIG. 11, operations 1105-1130 are similar to operations 505-530 of FIG. 5, respectively. The discussion of operations 505-530 applies to operations 1105-1130, unless mentioned otherwise. After operation 1130, structure of FIG. 12 is formed, which is similar to the structure of FIG. 9. The subsequent processing on the structure of FIG. 9 in operations 1135-1150 are described with reference to FIGS. 13-15.

Referring to FIG. 11, in operation 1135, other conductive lines and conductive pads are formed on the back-side of the flexible substrate. For example, as shown in FIG. 13, other conductive lines 102B and conductive pads 102C are formed on back-side 103s of flexible substrate 102A. The process for forming conductive lines 102B and conductive pads 102C on back-side 103s can be similar to the process for forming conductive lines 102B and conductive pads 102C on front-side 103f, as described in operation 505.

Referring to FIG. 11, in operation 1140, other electronic components are surface mounted on the back-side of the flexible substrate. For example, as shown in FIG. 13, other electronic components 104B and 104C are surface mounted on back-side 103s of flexible substrate 102A. The process for surface mounting electronic components 104B and 104C on back-side 103s can be similar to the process for surface mounting electronic components 104B and 104C on front-side 103f, as described in operation 515.

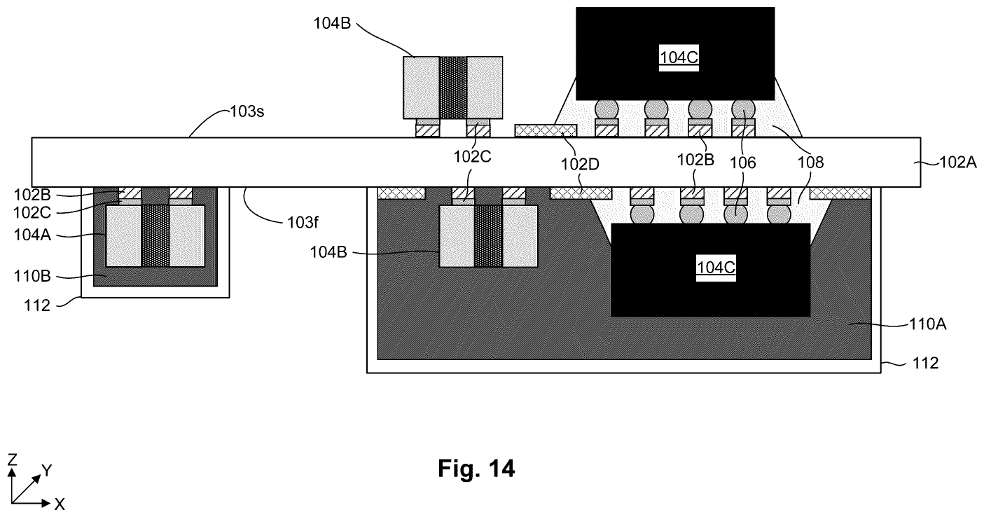

Referring to FIG. 11, in operation 1145, an other underfill layer is formed on the back-side of the flexible substrate. For example, as shown in FIG. 14, an other underfill layer 108 is formed on back-side 103s of flexible substrate 102A. The process for forming underfill layer 108 on back-side 103s can be similar to the process for forming underfill layer 108 on front-side 103f, as described in operation 520.

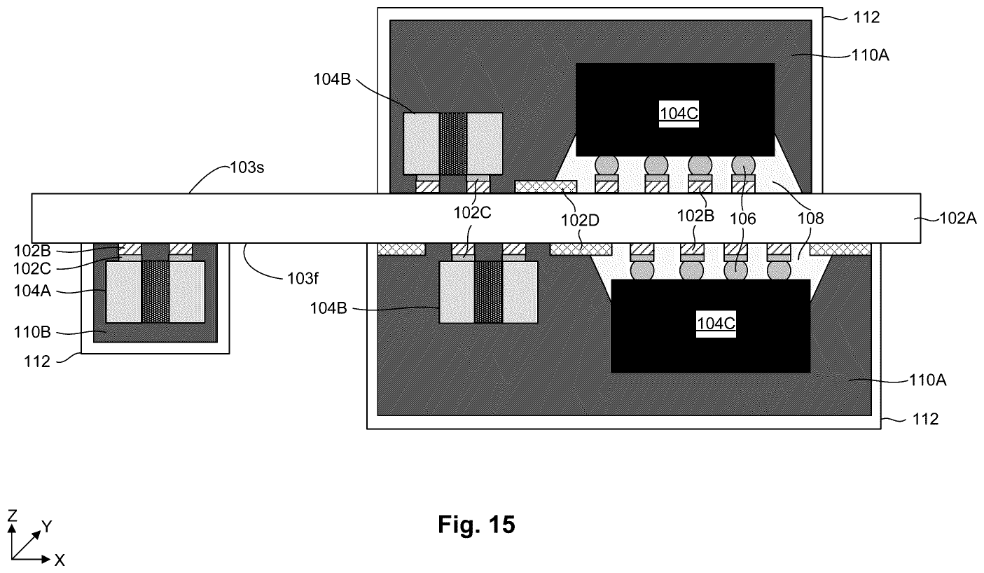

Referring to FIG. 11, in operation 1150, other molding compound layers are formed on the other electronic components. For example, as shown in FIG. 15, an other molding compound layer 110A is formed on electronic components 104B and 104C mounted on back-side 103s. In some embodiments, after the formation of the other molding compound layer 110A, an other shielding layer 112 can be deposited on the other molding compound layers 110A, as shown in FIG. 15.

In some embodiments, a CMP process can be performed on molding compound layer 110 on front-side 103f and a CMP process can be performed on the other molding compound layer 110 on back-side 103s to form flexible circuit package 301 shown in FIG. 3B.

In some embodiments, the above discussion of forming flexible circuit packages 300 and 301 applies to the formation of flexible circuit packages 400 and 401 shown in FIGS. 4A and 4B, respectively, except operation 515 is followed by operation 525 and operation 1140 is followed by operation 1150 to eliminate the formation of underfill layers 108 in flexible circuit packages 400 and 401.

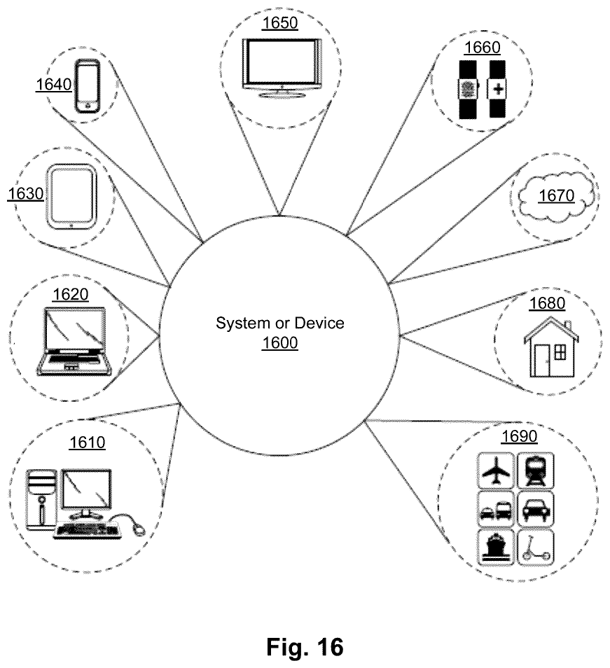

FIG. 16 is an illustration of exemplary systems or devices that can include the disclosed embodiments. System or device 1600 can incorporate one or more of the disclosed embodiments in a wide range of areas. For example, system or device 1600 can be implemented in one or more of a desktop computer 1610, a laptop computer 1620, a tablet computer 1630, a cellular or mobile phone 1640, and a television 1650 (or a set-top box in communication with a television).

Also, system or device 1600 can be implemented in a wearable device 1660, such as a smartwatch or a health-monitoring device. In some embodiments, the smartwatch can have different functions, such as access to email, cellular service, and calendar functions. Wearable device 1660 can also perform health-monitoring functions, such as monitoring a user's vital signs and performing epidemiological functions (e.g., contact tracing and providing communication to an emergency medical service). Wearable device 1660 can be worn on a user's neck, implantable in user's body, glasses or a helmet designed to provide computer-generated reality experiences (e.g., augmented and/or virtual reality), any other suitable wearable device, and combinations thereof.

Further, system or device 1600 can be implemented in a server computer system, such as a dedicated server or on shared hardware that implements a cloud-based service 1670. System or device 1600 can be implemented in other electronic devices, such as a home electronic device 1680 that includes a refrigerator, a thermostat, a security camera, and other suitable home electronic devices. The interconnection of such devices can be referred to as the “Internet of Things” (IoT). System or device 1600 can also be implemented in various modes of transportation 1690, such as part of a vehicle's control system, guidance system, and/or entertainment system. The systems and devices illustrated in FIG. 16 are merely examples and are not intended to limit future applications of the disclosed embodiments. Other example systems and devices that can implement the disclosed embodiments include portable gaming devices, music players, data storage devices, and unmanned aerial vehicles.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a substrate with first and second regions, wherein the first region is configured to bend;
a conductive line disposed on the second region;
an electronic component disposed on the conductive line; and
a molding compound layer disposed on the second region and surrounding the electronic component, wherein a modulus of the molding compound layer is greater than a modulus of the substrate, and wherein the molding compound layer is configured to prevent the second region from bending.

2. The structure of claim 1, further comprising an underfill layer disposed between the electronic component and a top surface of the second region.

3. The structure of claim 1, wherein a portion of the molding compound layer is disposed between the electronic component and a top surface of the second region.

4. The structure of claim 1, wherein the molding compound layer extends over a top surface of the electronic component.

5. The structure of claim 1, wherein a surface of the molding compound layer is substantially coplanar with a surface of the electronic component.

6. The structure of claim 1, wherein the molding compound layer comprises a substantially linear top surface profile and a substantially linear sidewall profile.

7. The structure of claim 1, wherein the molding compound layer comprises a modulus greater than about 15 GPa.

8. The structure of claim 1, wherein the molding compound layer is non-conformal to surfaces of the electronic component.

9. The structure of claim 1, further comprising solder bonding structures disposed between the electronic component and the second region, wherein the molding compound layer surrounds the solder bonding structures.

10. The structure of claim 1, further comprising a metal layer disposed substantially conformally on the molding compound layer.

11. A structure, comprising:
a substrate with first and second regions, wherein the first region is configured to bend;
a first conductive line disposed on a first surface of the second region;
a second conductive line disposed on a second surface of the second region, wherein the first and second surfaces are opposite to each other;
a first electronic component disposed on the first conductive line;
a second electronic component disposed on the second conductive line;
a first molding compound layer disposed on the first surface of the second region and surrounding the first electronic component; and
a second molding compound layer disposed on the second surface of the second region and surrounding the second electronic component, wherein a first modulus of the first molding compound layer is greater than a modulus of the substrate and a second modulus of the second molding compound layer is greater than the modulus of the substrate.

12. The structure of claim 11, wherein a portion of the first molding compound layer overlaps with a second portion of the molding compound layer.

13. The structure of claim 11, wherein a portion of the first molding compound layer is disposed between the first electronic component and the first surface of the second region; and
wherein a portion of the second molding compound layer is disposed between the second electronic component and the second surface of the second region.

14. The structure of claim 11, further comprising an underfill layer disposed between the first electronic component and the first surface of the second region.

15. The structure of claim 11, wherein a surface of the first molding compound layer is substantially coplanar with a surface of the first electronic component; and
wherein a surface of the second molding compound layer is substantially coplanar with a surface of the second electronic component.

16. The structure of claim 11, wherein the first and second molding compound layers comprise a modulus greater than about 15 GPa.

17. A method, comprising:
forming a conductive line on a first surface of a flexible substrate;
mounting a rigid substrate on a second surface of the flexible substrate, wherein the first and second surfaces are opposite to each other;
bonding an electronic component on the conductive line;
forming a molding compound layer surrounding the electronic component; and
removing the rigid substrate.

18. The method of claim 17, wherein forming the molding compound layer comprises depositing a molding compound with a modulus greater than about 15 GPa on the electronic component.

19. The method of claim 17, further comprising performing a planarization process on the molding compound layer to coplanarize a surface of the molding compound layer with a surface of the electronic component.

20. The method of claim 17, further comprising depositing a metal layer on the molding compound layer.
